(19) United States
(12) Patent Application Publication
(10) Pub. No.: US 2019/0326138 A1
(43) Pub. Date: Oct. 24, 2019

(54) CERAMIC WAFER HEATER WITH INTEGRATED PRESSURIZED HELIUM COOLING

(71) Applicant: Applied Materials, Inc., Santa Clara, CA (US)

(72) Inventors: Paul F. FORDERHASE, Austin, TX (US); Luke BONECUTTER, Cedar Park, TX (US); Jason M. SCHALLER, Austin, TX (US)

(21) Appl. No.: 16/388,768

(22) Filed: Apr. 18, 2019

Related U.S. Application Data
(60) Provisional application No. 62/660,937, filed on Apr. 20, 2018.

(51) Int. Cl. H01L 21/67; H01L 21/683; H01J 37/32

(52) U.S. Cl. CPC H01L 21/67109; H01J 37/32724; H01L 21/67248; H01L 21/6833

(57) ABSTRACT

Embodiments of the present disclosure generally provide apparatus and methods for cooling a substrate support. In one embodiment the present disclosure provides a cooling system for a substrate support. The cooling system includes a substrate support with cooling channels located within the substrate support, a heat exchanger fluidly coupled to the cooling channels, a compressor fluidly coupled to the heat exchanger, a cooling fluid supply source fluidly coupled to the cooling fluid system and a vacuum pump.

### CROSS-REFERENCE TO RELATED APPLICATIONS

This application claims benefit of U.S. provisional patent application Ser. No. 62/660,937, filed Apr. 20, 2018, which is hereby incorporated herein by reference.

### BACKGROUND

### Field

Embodiments of the present disclosure generally relate to semiconductor substrate processing systems. More specifically, embodiments of the disclosure relate to a method and apparatus for controlling temperature of a substrate in a semiconductor substrate processing system.

### Description of the Related Art

In the manufacture of integrated circuits, precise control of various process parameters achieves consistent process results on an individual substrate, as well as process results that are reproducible from substrate to substrate. As the geometry limits of the structures for forming semiconductor devices are pushed against technology limits, tighter tolerances and precise process control improve fabrication success. However, with shrinking device and feature geometries, more precise critical dimension requirements and higher processing temperatures, chamber process control has become increasingly difficult. During high temperature processing, changes in the temperature and/or temperature gradients across the substrate negatively impact deposition uniformity, material deposition rates, step coverage, feature taper angles, and other process parameters and results on semiconductor devices.

A substrate support pedestal is predominantly utilized to control the temperature of a substrate during processing, generally through control of backside gas distribution and the heating and cooling of the pedestal itself, and thus heating or cooling of a substrate on the support. Although conventional substrate pedestals have proven to be robust performers at larger substrate critical dimension requirements and lower substrate process temperatures, existing techniques for controlling the substrate temperature distribution across the diameter of the substrate should be improved in order to enable fabrication of next generation structures formed using higher processing temperatures.

Therefore, there is a need in the art for an improved method and apparatus for controlling temperature of a substrate during high temperature processing of the substrate in a semiconductor substrate processing apparatus.

### SUMMARY

Embodiments of the present disclosure generally provide apparatus and methods for cooling a substrate support. In one embodiment the present disclosure provides a cooling fluid system, the cooling fluid system includes a substrate support and cooling channels located within the substrate support and having an inlet and an outlet. The cooling fluid system further includes a conduit that is fluidly coupled at a first end to the inlet of the cooling channels and fluidly coupled to the outlet of the cooling channels at a second end, a heat exchanger fluidly coupled to the conduit between the first and second ends, and a compressor fluidly coupled to the conduit between the first and second end.

In one embodiment the present disclosure provides a cooling fluid system having an electrostatic chuck, at least one cooling channel located within the electrostatic chuck and a heat exchanger fluidly coupled to the at least one cooling channel. The cooling fluid system further having a compressor fluidly coupled to the heat exchanger and the at least one cooling channel, and a fluid inlet port coupled to the at least one cooling channel, and configured to be coupled to a cooling fluid supply source, and a vacuum pump fluidly coupled to the at least one cooling channel.

In one embodiment the present disclosure provides a cooling fluid system having an electrostatic chuck, at least one cooling channel located within the electrostatic chuck and a heat exchanger fluidly coupled to the at least one cooling channel. The cooling fluid system further having a compressor fluidly coupled to the heat exchanger and the at least one cooling channel, a fluid inlet port coupled to the at least one cooling channel, and configured to be coupled to a cooling fluid supply source, and a vacuum pump fluidly coupled to the at least one cooling channel, wherein the electrostatic chuck further comprises a substrate support surface, a heating element and an electrode, wherein the heating element and the electrode are disposed between the substrate support surface and the at least one cooling channel.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a sectional schematic diagram of a semiconductor substrate processing apparatus comprising a substrate pedestal in accordance with one embodiment disclosed herein.

FIG. 2 is a schematic depiction of a closed loop fluid supply source in accordance with one embodiment disclosed herein.

### DETAILED DESCRIPTION

The present disclosure generally provides a method and apparatus for controlling temperature of a substrate during processing thereof in a high temperature environment. Although the disclosure is illustratively described with respect to a semiconductor substrate plasma processing apparatus including plasma etch and plasma deposition processes, the subject matter of the disclosure may be utilized in other processing systems, including non-plasma etch, deposition, implant and thermal processing, or in other application where control of the temperature profile of a substrate or other workpiece is desirable.

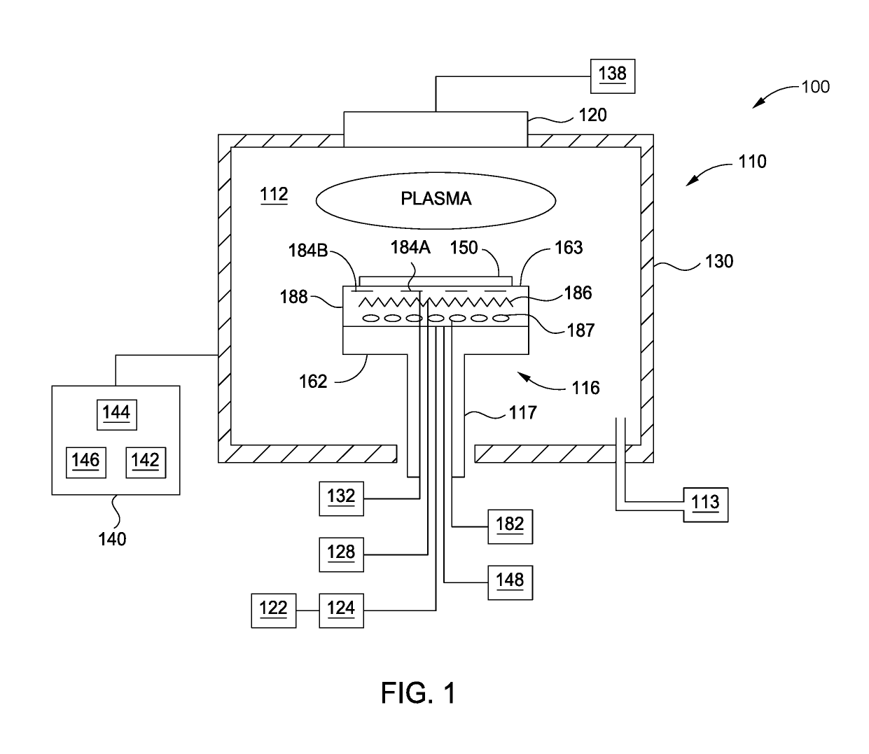

FIG. 1 depicts a schematic view of a substrate processing system 100 having one embodiment of a substrate support assembly 116 having an integrated pressurized cooling system 182. The particular embodiment of the substrate processing system 100 shown herein is provided for illustrative purposes and should not be used to limit the scope of the disclosure.

Processing system 100 generally includes a process chamber 110, a gas panel 138 and a system controller 140. The process chamber 110 includes a chamber body (wall) 130 and a showerhead 120 that enclose a process volume 112. Process gasses from the gas panel 138 are provided to the process volume 112 of the process chamber 110 through the showerhead 120. A plasma may be created in the process volume 112 to perform one or more processes on a substrate held therein. The plasma is, for example, created by coupling power from a power source (e.g., RF power source 122) to a process gas via one or more electrodes (described below) within the chamber process volume 112 to ignite the process gas and create the plasma.

The system controller 140 includes a central processing unit (CPU) 144, a memory 142, and support circuits 146. The system controller 140 is coupled to and controls components of the processing system 100 to control processes performed in the process chamber 110, as well as may facilitate an optional data exchange with databases of an integrated circuit fab.

The process chamber 110 is coupled to and in fluid communication with a vacuum system 113, which may include a throttle valve (not shown) and vacuum pump (not shown) which are used to exhaust the process chamber 110. The pressure within the process chamber 110 may be regulated by adjusting the throttle valve and/or vacuum pump, in conjunction with gas flows into the chamber process volume 112.

The substrate support assembly 116 is disposed within the interior chamber process volume 112 for supporting and chucking a substrate 150, such as a semiconductor wafer or other such substrate as may be electrostatically retained. The substrate support assembly 116 generally includes a pedestal assembly 162 for supporting electrostatic chuck 188. The pedestal assembly 162 includes a hollow support shaft 117 which provides a conduit for piping to provide gases, fluids, heat transfer fluids, power, or the like to the electrostatic chuck 188.

The electrostatic chuck 188 is generally formed from ceramic or similar dielectric material and comprises at least one clamping electrode 186 controlled using a power supply 128. In a further embodiment, the electrostatic chuck 188 may comprise at least one RF electrode (not shown) coupled, through a matching network 124, to an RF power source 122. The electrostatic chuck 188 may optionally comprise one or more substrate heaters. In one embodiment, two concentric and independently controllable resistive heaters, shown as concentric heating elements 184A, 1846, coupled to power source 132, are utilized to control the edge to center temperature profile of the substrate 150.

The electrostatic chuck 188 further includes a plurality of gas passages (not shown), such as grooves, that are formed in a substrate supporting surface 163 of the electrostatic chuck 188 and fluidly coupled to a source 148 of a heat transfer (or backside) gas. In operation, the backside gas (e.g., helium (He)) is provided at a controlled pressure into the gas passages to enhance the heat transfer between the electrostatic chuck 188 and the substrate 150. In some examples, at least the substrate supporting surface 163 of the electrostatic chuck 188 is provided with a coating resistant to the chemistries and temperatures used during processing of the substrates.

The electrostatic chuck 188 includes one or more cooling channels 187 that are coupled to the cooling system 182. A heat transfer fluid, which may be at least one gas such as Freon, Argon, Helium or Nitrogen, among others, or a liquid such as water, Galvan, or oil, among others, is provided by the cooling system 182 through the cooling channels 187. The heat transfer fluid is provided at a predetermined temperature and flow rate to control the temperature of the electrostatic chuck 188 and to control, in part, the temperature of a substrate 150 disposed on the substrate support assembly 116. The temperature of the substrate support 116 is controlled to maintain the substrate 150 at a desired temperature, or change the substrate temperature between desired temperatures during processing. The cooling channels 187 may be fabricated into the electrostatic chuck 188 below heating elements 184A and 184B, clamping electrode 186 and RF electrode (not shown). Alternatively, in one example, the cooling channels 187 are disposed in the pedestal assembly 162, below the electrostatic chuck 188.

Cooling fluid is routed through cooling channels 187 to remove excess heat from the electrostatic chuck 188. Heat is generated by the plasma within the process volume 112 and is absorbed by the substrate and thus the electrostatic chuck 188. In one embodiment, helium is used as the cooling fluid, particularly because helium is very effective at heat transfer when the plasma is a high temperature plasma using large amounts of RF energy to sustain the plasma above the substrate 150. Helium as a cooling gas has a number of advantages over other cooling mediums. For example, helium can be used for high temperature applications because helium, at a temperature greater than 4 degrees kelvin has no temperature limitations such as a boiling point that limits the amount of heat transfer, as compared to water, which has a boiling point at 100 degrees Celsius. Additionally, helium is readily available within a wafer processing environment and is neither flammable nor toxic.

Temperature of the substrate support assembly 116, and hence the substrate 150, is monitored using a plurality of sensors (not shown in FIG. 1). Routing of the sensors is through the pedestal assembly 162. The temperature sensors, such as a fiber optic temperature sensor, are coupled to the system controller 140 to provide a metric indicative of the temperature profile of the substrate support assembly 116 and electrostatic chuck 188.

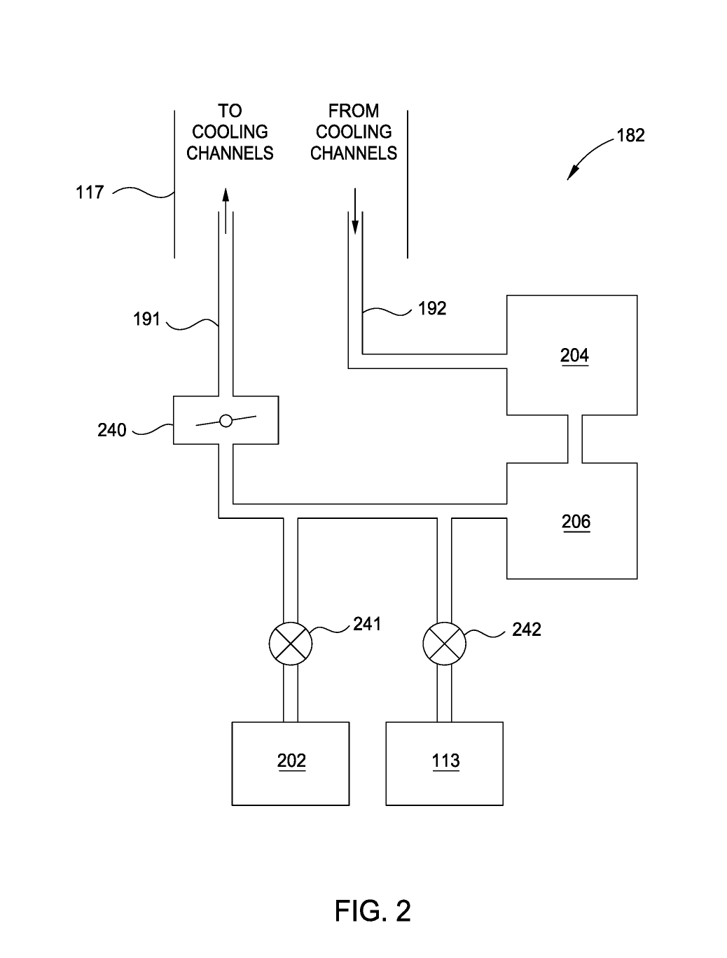

FIG. 2 is a schematic depiction of substrate support cooling system 182 shown in FIG. 1. In one embodiment, cooling system 182 is a closed loop fluid supply system used to provide a heat transfer fluid at a desired set point temperature and flow rate to the electrostatic chuck 188 during plasma processing. For example, when using helium as the heat transfer fluid for the electrostatic chuck 188, the helium coming from cooling channels 187 is cooled in the heat exchanger 204 and then is then routed again to the cooling channels 187 to cool, i.e., remove heat from, the electrostatic chuck 188. A non-closed loop system would cool the electrostatic chuck 188 by continually providing a helium gas at a set point temperature and flow rate from an external helium gas supply source and then discarding the heated helium gas once the heated helium has been through the cooling channels 187. By using the helium in a closed loop process, the amount and cost of the helium is limited, but also the temperature and flow rate of the helium routed to the electrostatic chuck 188 may be closely regulated resulting in increased control of the temperature set point of the electrostatic chuck 188 and the resulting process temperature of the substrate 150 thereon.

As shown in FIG. 2 and referring to FIG. 1, gas delivery conduit 191 and gas return conduit 192 are routed to and from the cooling channels 187 within electrostatic chuck 188 through the hollow support shaft 117 of pedestal assembly 162. An external helium supply source 202 is fluidly coupled to gas delivery conduit 191 to supply the helium gas to the cooling system 182. Control valve 241 is positioned between the external helium supply source 202 and the gas delivery conduit 191 to regulate the amount (flow rate) and the pressure of helium gas flow into the closed loop system.

In one embodiment, vacuum system 113 may be coupled to gas delivery conduit 191. As described above, vacuum system 113 includes a vacuum pump (not shown) used to exhaust the process chamber 110. By coupling the vacuum system 113 to the closed loop fluid supply, the system provides an existing source of vacuum to purge the closed loop system of air before the helium is introduced into the system from external helium supply source 202. By using the existing vacuum system 113, a separate purge vacuum is not required, or alternatively, gas from helium supply source 202 is not needed to purge the closed loop system of air. Control valve 242 is positioned between the vacuum system 113 and gas delivery conduit 191 to regulate the purge of the closed loop system.

Gas return conduit 192 delivers the heated gas from the cooling channels 187 within electrostatic chuck 188 via hollow support shaft 117 of pedestal assembly 162 (shown in FIG. 1) to the heat exchanger 204. Heat is removed from the helium gas by the heat exchanger 204. The heat exchanger 204 is coupled to facility cooling water (not shown) and the facility cooling water transfers the waste heat from the helium gas to the facility cooling water. The amount of heat removed from the helium gas is monitored and controlled by the system controller 140 (shown in FIG. 1). The system controller 140 regulates the heat exchanger 204 and thus the degree the helium gas is cooled based on the chamber process conditions including the temperature of the plasma, the temperature of the substrate support assembly 116 and the target processing temperature of the substrate 150, among others.

Compressor 206 is fluidly connected to the heat exchanger 204 and increases the pressure of the helium gas through the cooling channels 187 in the electrostatic chuck 188. It has been found that the heat transfer, i.e., the heat removal rate of heat from the electrostatic chuck into the helium gas, is increased by increasing the density of the helium gas. To facilitate the increased heat transfer, the compressor 206 provides an increased working pressure and provides the helium gas at a higher flow rate. By increasing the pressure of the helium gas, the mass flow rate is increased for any given volume flow rate. Because the mass flow rate of the helium gas, e.g., the change in density of helium in the gas flow changes the mass flow rate, governs the amount of heat removed by the helium gas, an increase in working pressure in the closed loop fluid supply system increases the heat removal rate by the ratio of working pressure to atmospheric pressure. The compressor 206 is used to increase the working pressure of the helium. The compressor is also used to maintain the working pressure and overcome the high head loss associated with the pressure drop of the helium gas due to the friction associated with the orientation of the gas delivery conduits 191 and 192, cooling channels 187 and other cooling system components to pump the helium through the cooling system. The compressor 206 and the flow rate of the closed loop fluid supply system are controlled by the system controller 140 and are controlled in conjunction with the control of the temperature of the electrostatic chuck 188. Throttle valve 240 may be used to regulate the helium flow through the system, but alternatively, any manner of controlling flow may be used, such as driving the compressor via a DC motor or AC motor with a variable frequency drive. Both DC motors and variable frequency drives provide a variable motor speed and thus, a variable, controllable flow.

In operation, helium is supplied into the cooling system from helium supply source 202 to a desired pressure, and thus mass of helium per cubic centimeter (cc), in the cooling circuit, and then control valve 241 is closed to isolate helium supply source 202 from the cooling circuit. The helium gas is flowed by the pressure of the compressor 206 and is thus introduced to the cooling channels 187 within the electrostatic chuck 188. The heating elements 184A and 184B (shown in FIG. 1) are energized to elevate the temperature of the electrostatic chuck 188 and substrate 150 to the target, or set point, processing temperature. For example a target temperature of the electrostatic chuck may be between 200 degrees Celsius and 700 degrees Celsius, such as 300 degrees Celsius. When the electrostatic chuck temperature is reached, RF power is applied to strike a plasma within process volume 112. As the substrate 150 and electrostatic chuck 188 absorb the heat energy from the plasma, the helium flow rate is controlled to maintain the desired operating target temperature, i.e., the set point temperature, of the electrostatic chuck 188 and to prevent the electrostatic chuck 188 from overheating.

In one operation, the helium flow rate through the cooling channels 187 of the electrostatic chuck 188 is maintained at a constant flow rate to absorb the heat energy from the electrostatic chuck 188 while the energy to the heating elements 184A and 184B is variably controlled by the system controller 140 to maintain the desired operating target temperature of the electrostatic chuck 188 during processing.

In one operation, both the energy to the heating elements 184A and 184B of electrostatic chuck 188 and the helium flow rate through the cooling channels 187 of the electrostatic chuck 188 are variably controlled by the system controller 140 to provide the desired operating temperature or temperatures of the electrostatic chuck 188 during the operation processing window.

The arrangement of the helium supply source 202, the heat exchanger 204, compressor 206 and vacuum system 113 of cooling system 182 is for illustrative purposes only and need not be provided in the order and arrangement as shown in FIG. 2. Rather, the arrangement of these components may be in any order that efficiently fit within the chamber's system architecture, footprint and the desired locations within the fab and subfab as needed.

While the foregoing is directed to embodiments of the present disclosure, other and further embodiments of the disclosure may be devised without departing from the basic scope thereof.

What is claimed is:

1. A cooling fluid system, comprising:
a substrate support;
cooling channels disposed within the substrate support and having an inlet and an outlet;
a conduit that is fluidly coupled at a first end the inlet of the cooling channels and fluidly coupled to the outlet of the cooling channels at a second end;
a heat exchanger fluidly coupled to the conduit between the first end and the second end; and
a compressor fluidly coupled to the conduit between the first end and the second end.

2. The cooling fluid system of claim 1, wherein the cooling fluid system is a closed-loop cooling system.

3. The cooling fluid system of claim 1, further comprising a vacuum system fluidly coupled to the cooling fluid system.

4. The cooling fluid system of claim 3, wherein the vacuum system comprises a vacuum pump fluidly coupled to a processing chamber within which the substrate support is located.

5. The cooling fluid system of claim 1, wherein the substrate support further comprises an electrostatic chuck, and the cooling channels are disposed within the electrostatic chuck.

6. The cooling fluid system of claim 5, wherein the substrate support further comprises heating elements and an electrode.

7. The cooling fluid system of claim 5, wherein the substrate support is coupled to a support shaft, and the conduit is located within the support shaft.

8. The cooling fluid system of claim 1, wherein the cooling fluid supply source is a helium gas source.

9. The cooling fluid system of claim 1, wherein the compressor comprises a variable speed DC motor.

10. The cooling fluid system of claim 1, wherein the compressor comprises an AC motor with a variable frequency drive.

11. The cooling fluid system of claim 1, further comprising a throttle valve.

12. A cooling fluid system comprising:
an electrostatic chuck;
at least one cooling channel located within the electrostatic chuck;
a heat exchanger fluidly coupled to the at least one cooling channel;
a compressor fluidly coupled to the heat exchanger and the at least one cooling channel;
a fluid inlet port coupled to the at least one cooling channel, and configured to be coupled to a cooling fluid supply source; and
a vacuum pump fluidly coupled to the at least one cooling channel.

13. The cooling fluid system of claim 12, wherein the cooling fluid system is a closed-loop cooling system.

14. The cooling fluid system of claim 12, wherein the vacuum pump is fluidly coupled to the cooling channel.

15. The cooling fluid system of claim 14, wherein the vacuum pump is also coupled to a processing chamber within which the electrostatic chuck is located.

16. The cooling fluid system of claim 12, wherein the cooling fluid supply source comprises a helium gas source.

17. The cooling fluid system of claim 12, wherein the compressor further comprises a variable speed DC motor.

18. The cooling fluid system of claim 12, wherein the compressor further comprises an AC motor with a variable frequency drive.

19. The cooling fluid system of claim 12, further comprising a throttle valve.

20. A cooling fluid system comprising:
an electrostatic chuck;
at least one cooling channel located within the electrostatic chuck;
a heat exchanger fluidly coupled to the at least one cooling channel;
a compressor fluidly coupled to the heat exchanger and the at least one cooling channel;
a fluid inlet port coupled to the at least one cooling channel, and configured to be coupled to a cooling fluid supply source; and
a vacuum pump fluidly coupled to the at least one cooling channel, wherein the electrostatic chuck further comprises a substrate support surface, a heating element and an electrode, wherein the heating element and the electrode are disposed between the substrate support surface and the cooling channel.
